(19) United States
(12) Patent Application Publication
(10) Pub. No.: US 2003/0151051 A1
(43) Pub. Date: Aug. 14, 2003

(54) High performance active and passive structures based on silicon material grown epitaxially or bonded to silicon carbide substrate

(75) Inventors: Joseph H. Johnson, Phoenix, AZ (US); Pablo D'Anna, Redding, CA (US)

Correspondence Address: Law Offices of Boris G. Tankhilevich, Suite A, 536 N. Civic Drive, Walnut Creek, CA, 94596, US

(73) Assignee: XEMOD, Inc.

(21) Appl. No.: 10/078,588

(22) Filed: Feb. 14, 2002

(51) Int. Cl. H01L 31/0312

(52) U.S. Cl. 257/77

(57) ABSTRACT

The present invention discloses and claims the silicon carbide based silicon structure comprising: (1) a silicon carbide substrate, (2) a silicon semiconductor material having a top surface, and either bonded to the silicon carbide substrate via the bonding layer, or epitaxially grown on the silicon carbide substrate; and (3) at least one separation plug formed in the silicon semiconductor material. The separation plug extends from the top surface of the silicon semiconductor material into the silicon carbide substrate at a separation plug depth level, and is configured to block the coupling between at least two adjacent active/passive structures formed in the silicon semiconductor material.

### BACKGROUND OF THE INVENTION

1. Field of the Invention

The present invention is in the field of silicon fabricated integrated circuits (ICs). More specifically, the present invention relates to silicon fabricated ICs based on silicon material grown epitaxially or bonded to silicon carbide (SiC) substrate in order to improve the heat dissipation of silicon fabricated ICs while retaining the advantages of easiness of processing that the mature silicon technology provides in order to compete with ICs fabricated on more exotic materials.

2. Discussion of the Prior Art

In the prior art, there were numerous attempts to improve electrical performance of devices built on ICs. More specifically, circuits based on ICs have been fabricated in a number of material combinations of active layers and substrates in order to obtain advantages in circuit performance. For instance, GaAs was the first III-V compound material investigated to fabricate high electrical performance circuits. Also, lately SiC and even diamond have been tested as possible substitute materials that could be used to fabricate high performance IC circuits.

Notwithstanding this variety of possibilities, silicon remains the material of choice for the fastest high volume production of IC circuits in the world. In fact, the question now is not how to obtain higher electrical performance out of silicon based IC circuits, but how to improve the thermal dissipation of devices built on silicon based IC. Indeed, since tighter and smaller geometries are being used to improve speed of operation of devices built on silicon based IC circuits, the single and most important limitation factor on speed of operation of such devices is that small and geometrically tight silicon based IC circuits experience a relatively high thermal dissipation when used at high frequencies and high applied voltages, and therefore could reach relatively high operational temperatures that would adversely affect the RF high power performance and reliability of such devices. This relatively high thermal dissipation has also affected the performance of IC circuits fabricated on Ill-V compounds, as their thermal dissipation characteristics are generally worse than the thermal dissipation characteristics of silicon based IC circuits.

To remove the thermal dissipation limitation, circuits were built on SiC and diamond materials. However, while these materials offer an advantage in terms of thermal dissipation, their wide band gap and extreme thermal stability present problems in certain commonly used active device fabrication steps such as ion implantation, contact fabrication, etc. Moreover, crystal growth, epitaxial layer growth, and general device processing technologies are still immature to produce reliable device structures based exclusively on SiC and diamond.

Recently, a new technique of growing epitaxial compound semiconductor layers on top of large silicon substrates was introduced. This technique presents an improvement over GaAs based technologies because it allows one to obtain a larger wafer size. It also gives an improvement on thermal dissipation since silicon is a better heat conductor than most of Ill-V compounds. Growing epitaxial SiC layers on top of the silicon material has been also done as a means for obtaining large diameter wafers with fewer defects.

What is needed is to combine the easiness of silicon based IC fabrication with the advantages and insulating properties of SiC utilized as a substrate material to provide an IC structure that includes a high thermal conductivity and that is also capable of suppressing coupling between active/passive devices built using such an IC structure.

### SUMMARY OF THE INVENTION

To address the shortcomings of the available art, the present invention provides high performance active and passive structures based on silicon material grown epitaxially or bonded to silicon carbide substrates.

One aspect of the present invention is directed to a silicon carbide based silicon structure comprising: (1) a silicon carbide substrate, (2) a bonding layer overlying the silicon carbide substrate, and (3) a silicon semiconductor overlaying the bonding layer and bonded to the silicon carbide substrate via the bonding layer.

Another aspect of the present invention is directed to a silicon carbide based silicon structure comprising: (1) a silicon carbide substrate, and (2) a silicon semiconductor grown on the silicon carbide substrate.

In one embodiment, the silicon carbide based silicon structure of the present invention further includes at least one separation plug formed in the silicon semiconductor material. In one embodiment, the separation plug extends from the top surface of the silicon semiconductor material into the silicon carbide substrate at a separation plug depth level and is configured to block the coupling between at least two adjacent active/passive structures formed in the silicon semiconductor material.

The silicon carbide substrate is of a first conductivity type and has a first dopant concentration, whereas the silicon semiconductor material is of a second conductivity type, and includes a second dopant concentration.

In one embodiment of the present invention, the first dopant concentration of the silicon carbide substrate is equal or greater than the second dopant concentration of the silicon semiconductor material. In another embodiment, the first dopant concentration of the silicon carbide substrate is lower than the second dopant concentration of the silicon semiconductor material.

In one embodiment of the present invention, the first conductivity of the silicon carbide is of P type. In another embodiment, the first conductivity of the silicon carbide is of N type. In one embodiment of the present invention, the second conductivity type of the semiconductor material is of P type. In an alternative embodiment, the second conductivity type of the semiconductor material is of N type.

In one embodiment, the silicon carbide substrate further includes a plurality of N silicon carbide layers. More specifically, in this embodiment, the first silicon carbide layer includes a bottom surface of the silicon carbide substrate, the last N-th layer includes a top surface of the silicon carbide substrate, and each subsequent “k”-th layer having a “k”-th dopant concentration overlies the preceding “k−1”-th layer having a “k−1”-th dopant concentration. Each subsequent “k”-th silicon carbide layer is grown on the preceding “k−1”-th silicon carbide layer, wherein “k” is an integer greater than 1, and less or equal to N; N is an integer. In one embodiment, the “k”-th silicon carbide layer has a “k”-th conductivity type comprising the first conductivity type. In another embodiment, the “k”-th silicon carbide layer has a “k”-th conductivity type comprising the second conductivity type.

In one embodiment, at least one silicon carbide layer further comprises an epitaxially grown by a Chemical Vapor Deposition (CVD) process silicon carbide layer, or an epitaxially grown by a molecular beam epitaxy (MBE) process silicon carbide layer.

In one embodiment, the silicon semiconductor material further includes a plurality of M silicon semiconductor material layers, the first silicon semiconductor material layer including a bottom surface of the silicon semiconductor material, the last M-th layer including a top surface of the silicon semiconductor material, and “M-2” intermediate layers, M is an integer. Each subsequent “i”-th layer overlies the preceding “i−1”-th layer. Each “i”-th silicon semiconductor material layer having an “i”-th dopant concentration is grown on the preceding “i−1”-th silicon semiconductor material layer, whereas “i” is an integer greater than 1, and less or equal to M.

In one embodiment, each “i”-th silicon semiconductor material layer has an “i”-th conductivity type comprising the first conductivity type. In another embodiment, each “i”-th silicon semiconductor material layer has an “i”-th conductivity type comprising the second conductivity type.

In one embodiment, at least one silicon semiconductor material layer further comprises an epitaxially grown by a Chemical Vapor Deposition (CVD) process silicon semiconductor material layer, or an epitaxially grown by a molecular beam epitaxy (MBE) process silicon semiconductor material layer.

The bonding layer further comprises: a silicon dioxide layer, a silicon layer, a carbon layer, or a metal silicided layer including a tungsten silicide layer, a titanium silicide layer, or a cobalt silicide layer.

In one embodiment, the separation plug further includes a trench filled with a material including an oxide material, a polysilicon material, a metal material, a silicided material, a tungsten silicide material, a titanium silicide material, a cobalt silicide material, or a platinum silicide material.

### BRIEF DESCRIPTION OF DRAWINGS

The aforementioned advantages of the present invention as well as additional advantages thereof will be more clearly understood hereinafter as a result of a detailed description of a preferred embodiment of the invention when taken in conjunction with the following drawings.

FIG. 1A depicts a silicon carbide based silicon structure of the present invention comprising a silicon carbide substrate, a bonding layer overlying the silicon carbide substrate, and a silicon semiconductor material overlying the bonding layer and having a top surface.

FIG. 1B shows a silicon carbide based silicon structure of the present invention comprising the silicon carbide substrate further including a plurality of N silicon carbide layers, a bonding layer overlying the silicon carbide substrate, and a silicon semiconductor material further including a plurality of M silicon layers, N and M are integers.

FIG. 2 illustrates a silicon carbide based silicon structure of FIG. 1A further including at least one separation plug configured to block the coupling between at least two adjacent active/passive structures.

FIG. 3A depicts a silicon carbide based silicon structure of the present invention comprising a silicon carbide substrate and a silicon semiconductor material grown on the silicon carbide substrate and having a top surface.

FIG. 3B shows a silicon carbide based silicon structure of the present invention comprising the silicon carbide substrate further including a plurality of N silicon carbide layers, and a silicon semiconductor material further including a plurality of M silicon layers, N and M are integers

### DETAILED DESCRIPTION OF THE PREFERRED AND ALTERNATIVE EMBODIMENTS.

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

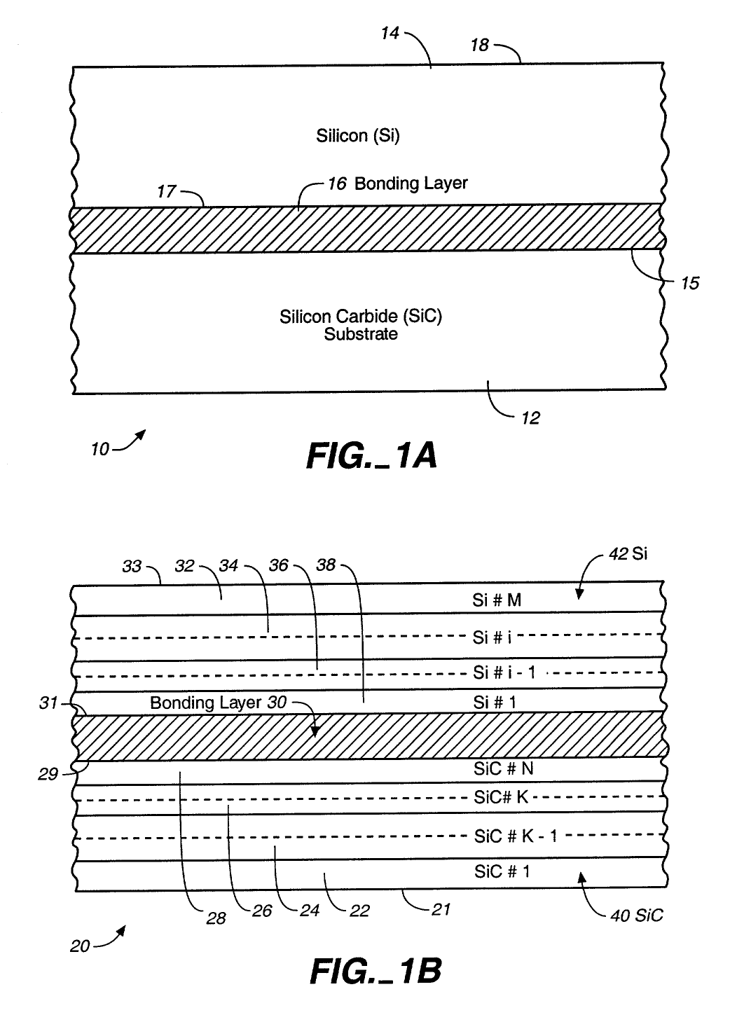

In one embodiment of the present invention, FIG. 1A depicts a silicon 20 carbide based silicon structure 10 comprising a silicon carbide substrate 12; a bonding layer 16 overlying the silicon carbide substrate 12, and a silicon semiconductor material 14 having a top surface 18. The silicon semiconductor material 14 is overlaying the bonding layer 16 and is bonded to the silicon carbide substrate 12 via the bonding layer 16.

In one embodiment of the present invention, the silicon carbide substrate 12 is of a first conductivity type (SiC)^{I} and includes a first dopant concentration (N/P)_{SiC}^{I}; wherein the silicon semiconductor material 14 is of a second conductivity type (Si)^{II} and has a second dopant concentration (N/P)_{Si}^{II}.

In one embodiment, the conductivity type of the silicon carbide (SiC)^{I} is of P type, that is the majority carriers in the silicon carbide substrate are holes. In another embodiment, the conductivity type of the silicon carbide (SiC)^{I} is of N type, that is the majority carriers in the silicon carbide substrate are electrons. In one embodiment, the conductivity type of the silicon semiconductor material (Si)^{II} is of P type, that is the majority carriers in the silicon semiconductor material are holes. In one more embodiment, the conductivity type of the silicon semiconductor material (Si)^{II} is of N type, that is the majority carriers in the silicon semiconductor material are electrons.

In one embodiment, the silicon semiconductor material is doped to be N-type by using ions of Arsenic, or ions of Phosphorous. In another embodiment, the silicon semiconductor material is doped to be P-type by using ions of Boron. In one embodiment, the SiC substrate is doped to be N type by using ions of Nitrogen. In another embodiment, the SiC substrate is doped to be P type by using ions of Aluminum.

Referring still to FIG. 1A, in one embodiment of the present invention, the dopant concentration (N/P)_{SiC}^{I/II} of the silicon carbide substrate is equal or greater than the dopant concentration (N/P)_{Si}^{I/II} of the silicon semiconductor material:

(N/P)_{SiC}^{I/II}≧(N/P)_{Si}^{I/II}. (1)

In another embodiment of the present invention, the dopant concentration (N/P)_{SiC}^{I/II} of the silicon carbide substrate is less than the dopant concentration (N/P)_{Si}^{I/II} of the silicon semiconductor material:

(N/P)_{SiC}^{I/II}<(N/P)_{Si}^{I/II}. (2)

Referring still to FIG. 1A, in one embodiment of the present invention, the bonding layer 16 comprises a silicon dioxide bonding layer. In one embodiment, a thin layer (500 Å-5000 Å) of silicon dioxide 16 is grown by oxidizing both the SiC top surface 15 and the silicon bottom surface 17, or by deposition of a thin (500 Å-2000 Å) layer of silicon dioxide to the bonding surfaces 16 and 17.

In another embodiment, the bonding layer 16 comprises a silicon layer. In one more embodiment, the bonding layer 16 further comprises a carbon layer. Yet, in one additional embodiment, the bonding layer 16 further comprises a metal silicided layer including a tungsten silicide layer, a titanium silicide layer, or a cobalt silicide layer. The thickness of bonding layer is typically in the range of (50-2000) Å.

In one embodiment, the silicon bonding layer can be formed by using a Chemical Vapor Deposition (CVD) process. The chemical vapor deposition (CVD) process is the process in which a film is deposited by a chemical reaction or decomposition of a gas mixture at elevated temperature at the wafer surface or in its vicinity. The typical examples of CVD films are a single crystal silicon film, a polycrystalline silicon film, a silicon dioxide film, a silicon-nitride film, or a SiC film. CVD can be performed at atmospheric pressure (APCVD), or at low pressure (LPCVD).

In one of the typical applications of epitaxial deposition, a lightly doped layer is deposited on a heavily doped substrate. The lightly doped layer is the region where active devices are constructed and the heavily doped substrate constitutes a low resistance circuit path.

In another typical application of epitaxial deposition, heavily doped layer is buried in a lightly doped region of opposite polarity. The heavily doped layer is first defined and formed in the substrate using lithography, etching, and doping techniques. For the complete reference, please, see “Fundamentals of Semiconductor Processing Technologies” by Badih El-Kareh, IBM Corporation, published by Kluwer Academic Publishers in 1995.

The epi layer can be intentionally doped while grown by adding controlled amounts of the dopant compounds to the gas stream. Typical dopant sources are hybrids of the impurity, such as phosphine (PH₃), arsine (AsH₃), antimonine (SbH₃), or diborane (B₂H₆).

Referring still to FIG. 1A, a carbon bonding layer 16 can be formed by using the CVD process, or by performing the selective etching of the top surface 15 of the SiC substrate 12 to remove small amounts of silicon while leaving the carbon exposed, or by combination of both processes wherein silicon is etched from the bonding SiC surface 15 and carbon is deposited by CVD on the silicon surface 17 to be bonded to the SiC substrate 12.

A tungsten silicide bonding layer can be deposited by using sputtering or by using the CVD process. A titanium silicide bonding layer, or a cobalt silicide layer can be formed by sputtering.

Sputtering is similar to a billiard-ball event. Ions are accelerated in an electric field toward a target of material to be deposited, where they “knock-off” (sputter) target atoms. The sputtered ions then deposited onto wafers which are conveniently placed facing the target. Argon ion (Ar⁺) is typically used for sputtering because it is inert and readily available in a pure form. It is ionized by colliding with high energy electrons in the chamber, and then accelerated in an electric field toward the negatively biased target. The momentum of ions incident on the target is then transferred to the surface atoms of the target material, causing ejection. Therefore, during sputter deposition, material is removed from the target and deposited onto wafers.

In one embodiment of the present invention, FIG. 1B shows a silicon carbide based silicon structure of the present invention 20 comprising the silicon carbide substrate 40 further including a plurality of N silicon carbide layers (22, 24, 26, . . . , 28), a bonding layer 30 overlying the silicon carbide substrate 40, and a silicon semiconductor material 42 further including a plurality of M silicon layers (38, 36, 34, . . . ,32), N and M are integers. The first silicon carbide layer 22 includes the bottom surface of the silicon carbide substrate 21. The last N-th silicon carbide layer 28 includes a top surface 29 of the silicon carbide substrate 40. Each subsequent “k”-th layer 26 is overlying the preceding “k−1”-th layer 24.

Referring still to FIG. 1B, in one embodiment of the present invention, each “k”-th silicon carbide layer 26 includes a “k”-th conductivity type comprising the first conductivity type (SiC)^{I}ₖ, or the second conductivity type (SiC)^{II}ₖ, wherein “k” is an integer greater than one and less or equal to N. Each “k”-th silicon carbide layer includes a “k”-th dopant concentration (N/P)_{SiC}^{I}, or (N/P)_{SiC}^{II}.

Each subsequent “k”-th silicon carbide layer 26 is grown on the preceding “k−1”-th silicon carbide layer 24. In one embodiment, at least one silicon carbide layer further comprises an epitaxially grown by CVD process silicon carbide layer, or an epitaxially grown by a molecular beam epitaxy (MBE) process silicon carbide layer. The epi layer can be intentionally doped while grown by adding controlled amounts of the dopant compounds to the gas stream.

### EXAMPLE I

The epi layer #1 of SiC 22, about 3-12 microns thick, is grown on the bottom SiC surface 21 of the SiC substrate 40 in the presence of Nitrogen.

As was stated above, in one embodiment, at least one silicon carbide layer further comprises an epitaxially grown by a molecular beam epitaxy (MBE) process silicon carbide layer.

Molecular beam epitaxy (MBE) is a sophisticated deposition technique performed in ultra high vacuum to grow compound semiconductors. High performance electronic, optoelectronic and photonic devices usually involve complex semiconductor heterostructure layers, and should be produced by advanced thin-film growth techniques such as MBE. In MBE, atoms of an element or compound are delivered to a substrate through an ultra-pure, ultra-high vacuum (UHV) atmosphere. The UHV atmosphere provided by the MBE chamber allows the atoms to arrive on the substrate without colliding with other atoms or molecules. This keeps the growth free of other contaminants. The heated substrate surface allows the arriving atoms to distribute themselves evenly across the surface to form an almost perfect crystal structure.

In MBE the substrate is placed in an UHV chamber with direct line of sight to several elemental species, each of which is in an evaporation furnace commonly referred to as an effusion cell. Through use of shutters and precise control of the effusion cell temperatures almost any material composition and doping can be achieved. Further, the composition may be controlled with a resolution of virtually one atomic layer. Applied Epi, formerly EPI MBE Products Group, based in St. Paul, Minn., USA, is a leader in MBE, and manufactures the GEN 2000™-designed to mass-produce epitaxial wafers.

Referring still to FIG. 1B, the silicon carbide based silicon structure 20 further includes a plurality of M silicon semiconductor material layers (38, 36, . . . , 34, 32). The first silicon semiconductor material layer 38 includes the bottom surface 31 of the silicon semiconductor material 42; wherein the last M-th layer 32 includes the top surface 33 of the silicon semiconductor material 42. Each subsequent “i”-th layer 34 is overlying the preceding “i−1”-th layer 36. Herein, “i” is an integer greater than 1 and less or equal to M, M is an integer.

Referring still to FIG. 1B, in one embodiment of the present invention, each “i”-th silicon layer 34 includes the “i”-th conductivity type comprising the first conductivity type (Si)^{I}ᵢ, or the second conductivity type (Si)^{II}ᵢ. Each “i”-th silicon layer includes an “i”-th dopant concentration (N/P)_{Si}^{I}, or (N/P)_{Si}^{II}.

At least one “i”-th silicon semiconductor material layer further comprises an epitaxially grown by CVD process silicon semiconductor material layer, or an epitaxially grown by MBE process silicon semiconductor material layer. Please, see discussion above.

### EXAMPLE II

The epi Si layer #1 38, about 3-12 microns thick, is grown on the top surface 31 of the bonding layer 30 in the presence of diborane (B₂H₆). This process results in a lightly Boron doped (P⁻) epi silicon layer #1 38.

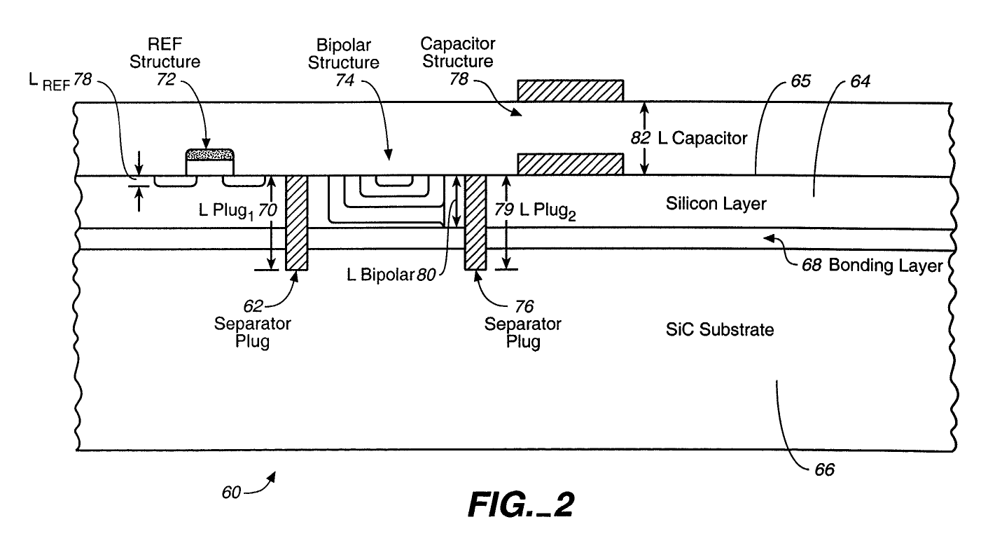

In one embodiment of the present invention, as depicted in FIG. 2, the silicon carbide based silicon structure 60 further includes at least one separation plug 62 formed in the silicon semiconductor material 64. The separation plug 62 extends from the top surface 65 of the silicon semiconductor material 64 into the silicon carbide substrate 66 at a separation plug depth level L_{Plug} (not shown). In general, each separation plug is configured to block the coupling between at least two adjacent active/passive structures, wherein the first active/passive structure extends from the top surface 65 of the silicon semiconductor material 64 into the silicon semiconductor material 64 at a first active/passive structure depth level L_{First active/passive} (not shown), and wherein the second active/passive structure extends from the top surface 65 of the silicon semiconductor material 64 into the silicon semiconductor material 64 at a second active/passive structure depth level L_{Second active/passive} (not shown).

In one embodiment of the present invention, as illustrated in FIG. 2, the first separation plug 62 extended at the separation plug depth level L_{Plug1} 70 separates the FET structure 72 extended at the FET structure depth level L_{FET} 78 from the bipolar structure 74 extended at the bipolar structure depth level L_{Bipolar} 80, and the second separation plug 76 extended at the separation plug depth level L_{Plug2} 79 separates the bipolar structure 74 extended at the bipolar structure depth level L_{Bipolar} 80 from the capacitor structure 78 extended at the capacitor structure depth level L_{Capacitor} 82.

In this embodiment, as shown in FIG. 2, the separation plug depth level L_{Plug1} of the first plug 62 is deeper than the FET structure depth level L_{FET} 78 and is deeper than the bipolar structure depth level L_{Bipolar} 80:

L_{Plug1}>L_{FET}; (3)

L_{Plug1}>L_{Bipolar}. (4)

Similarly, in this embodiment, as shown in FIG. 2, the separation plug depth level L_{Plug2} of the second plug 76 is deeper than the bipolar structure depth level L_{Bipolar} 80 and is deeper than the capacitor structure depth level L_{Capacitor} 82:

L_{Plug2}>L_{Bipolar}; (5)

L_{Plug2}>L_{Capacitor}. (6)

In one embodiment, the separation plug 62 further includes a trench (not shown) filled with a material comprising: an oxide material, a polysilicon material, a metal material, a silicided material, a tungsten silicide material, a titanium silicide material, a cobalt silicide material, or a platinum silicide material.

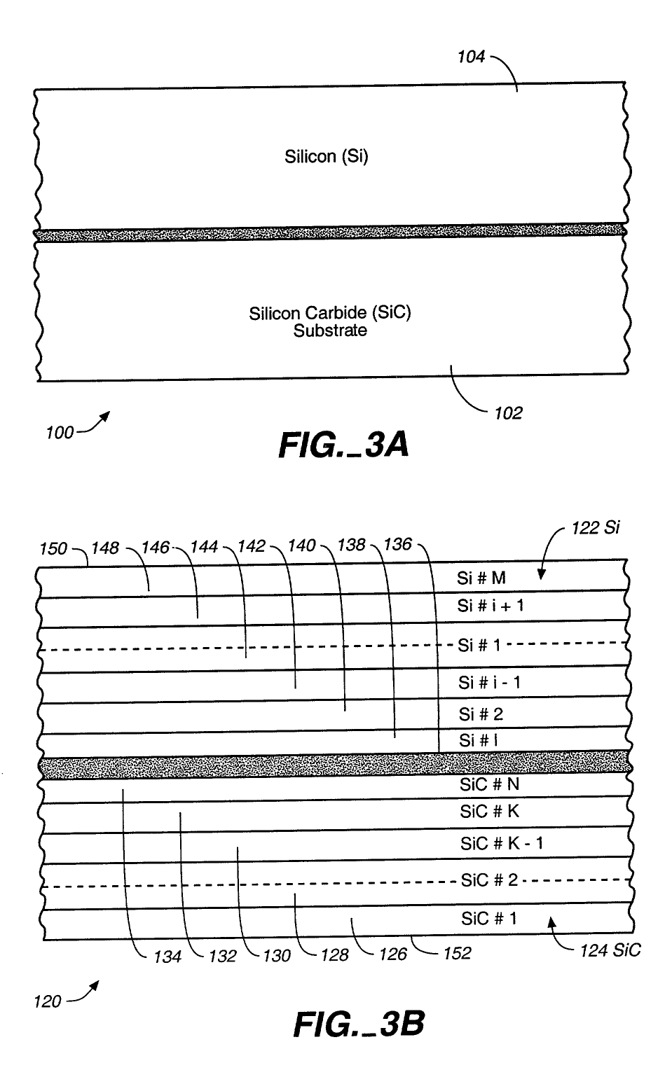

In one embodiment of the present invention, FIG. 3A illustrates a silicon carbide based silicon structure 100 further comprising a silicon carbide substrate 102, and a silicon semiconductor material 104 having a top surface 106. In this embodiment, the silicon semiconductor material 104 is epitaxially grown on the silicon carbide substrate 102.

In one embodiment of the present invention, the silicon carbide substrate 102 is of a first conductivity type (SiC)^{I} and includes a first dopant concentration (N/P)_{SiC}^{I}; wherein the silicon semiconductor material 104 is of a second conductivity type (Si)^{II} and has a second dopant concentration (N/P)_{Si}^{II}.

In one embodiment, the conductivity type of the silicon carbide (SiC)^{I} is of P type, that is the majority carriers in the silicon carbide substrate are holes. In another embodiment, the conductivity type of the silicon carbide (SiC)^{I} is of N type, that is the majority carriers in the silicon carbide substrate are electrons. In one embodiment, the conductivity type of the silicon semiconductor material (Si)^{II} is of P type, that is the majority carriers in the silicon semiconductor material are holes. In one more embodiment, the conductivity type of the silicon semiconductor material (Si)^{II} is of N type, that is the majority carriers in the silicon semiconductor material are electrons.

As was stated above, the silicon semiconductor material 104 can be doped to be N-type by using ions of Arsenic, or ions of Phosphorous, or can be doped to be P-type by using ions of Boron, whereas the SiC substrate 102 can be doped to be N type by using ions of Nitrogen, or can be doped to be P type by using ions of Aluminum.

Referring still to FIG. 3A, in one embodiment of the present invention, the dopant concentration (N/P)_{SiC}^{I/II} of the silicon carbide substrate is equal or greater than the dopant concentration (N/P)_{Si}^{I/II} of the silicon semiconductor material, according to Eq. (1). In another embodiment of the present invention, the dopant concentration (N/P)_{SiC}^{I/II} of the silicon carbide substrate is less than the dopant concentration (N/P)_{Si}^{I/II} of the silicon semiconductor material, according to Eq. (2).

In one embodiment of the present invention, FIG. 3B shows a silicon carbide based silicon structure of the present invention 120 comprising the silicon carbide substrate 124 further including a plurality of N silicon carbide layers (126, 128, 130, 132, . . . , 134), and a silicon semiconductor material 122 further including a plurality of M silicon layers (142, 144, 146, . . . , 148), N and M are integers. The first silicon carbide layer 126 includes the bottom surface of the silicon carbide substrate 152. The last N-th silicon carbide layer 134 includes a top surface 136 of the silicon carbide substrate 124. Each subsequent “k”-th layer 132 is overlying the preceding “k−1”-th layer 130.

Referring still to FIG. 3B, in one embodiment of the present invention, each “k”-th silicon carbide layer 132 includes a “k”-th conductivity type comprising the first conductivity type (SiC)^{I}ₖ, or the second conductivity type (SiC)^{II}ₖ, wherein “k” is an integer greater than one and less or equal to N. Each “k”-th silicon carbide layer includes a “k”-th dopant concentration (N/P)_{SiC}^{I}, or (N/P)_{SiC}^{II}.

Each subsequent “k”-th silicon carbide layer 132 is grown on the preceding “k−1”-th silicon carbide layer 130. In one embodiment, at least one silicon carbide layer further comprises an epitaxially grown by CVD process silicon carbide layer, or an epitaxially grown by a molecular beam epitaxy (MBE) process silicon carbide layer. Please, see discussion above.

Referring still to FIG. 3B, the silicon carbide based silicon structure 122 further includes a plurality of M silicon semiconductor material layers (138, 140, 142, 144, . . . , 146, 148). The first silicon semiconductor material layer 138 includes the bottom surface 136 of the silicon semiconductor material 122; wherein the last M-th layer 148 includes the top surface 150 of the silicon semiconductor material 122. Each subsequent “i”-th layer 144 is overlying the preceding “i−1”-th layer 142. Herein, “i” is an integer greater than 1 and less or equal to M, M is an integer.

Referring still to FIG. 3B, in one embodiment of the present invention, each “i”-th silicon layer 144 includes the “i”-th conductivity type comprising the first conductivity type (Si)^{I}ᵢ, or the second conductivity type (Si)^{II}ᵢ. Each “i”-th silicon layer includes an “i”-th dopant concentration (N/P)_{Si}^{I}, or (N/P)_{Si}^{II}.

At least one “i”-th silicon semiconductor material layer further comprises an epitaxially grown by CVD process silicon semiconductor material layer, or an epitaxially grown by MBE process silicon semiconductor material layer. Please, see discussion above.

In one embodiment of the present invention, the silicon carbide based silicon structure of FIG. 3A further includes at least one separation plug (not shown) formed in the silicon semiconductor material 104 and extending into the SiC substrate 102. The complete description of this embodiment can be found from the given above description of the silicon carbide based silicon structure of FIG. 1A further including at least one separation plug, as illustrated by structure 60 of FIG.2. This above given disclosure is fully applicable herein and is incorporated by reference.

The foregoing description of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A silicon carbide based silicon structure comprising:
a silicon carbide substrate;
a bonding layer overlying said silicon carbide substrate; and
a silicon semiconductor material having a top surface; said silicon semiconductor material overlaying said bonding layer; said silicon semiconductor material bonded to said silicon carbide substrate via said bonding layer.

2. The structure of claim 1, wherein said silicon carbide substrate is of a first conductivity type, said silicon carbide substrate having a first dopant concentration; said silicon semiconductor material being of a second conductivity type, said silicon semiconductor material having a second dopant concentration.

3. The structure of claim 2, wherein said first dopant concentration of said silicon carbide substrate is equal or greater than said second dopant concentration of said silicon semiconductor material.

4. The structure of claim 2, wherein said first dopant concentration of said silicon carbide substrate is lower than said second dopant concentration of said silicon semiconductor material.

5. The structure of claim 2, wherein said first conductivity of said silicon carbide is of P type.

6. The structure of claim 2, wherein said first conductivity of said silicon carbide is of N type.

7. The structure of claim 2, wherein said second conductivity type of said silicon semiconductor material is of P type.

8. The structure of claim 2, wherein said second conductivity type of said silicon semiconductor material is of N type.

9. The structure of claim 1; wherein said silicon carbide substrate further includes a plurality of N silicon carbide layers; wherein said first silicon carbide layer includes a bottom surface of said silicon carbide substrate; wherein said last N-th layer includes a top surface of said silicon carbide substrate; each said subsequent “k”-th layer overlying said preceding “k−1”-th layer; each said “k”-th silicon carbide layer having a “k”-th conductivity type comprising said first conductivity type, or said second conductivity type; each said “k”-th silicon carbide layer having a “k”-th dopant concentration; each said subsequent “k”-th silicon carbide layer being grown on said preceding “k−1”-th silicon carbide layer; “k” is an integer greater than 1, “k” is an integer less or equal to N, N is an integer.

10. The structure of claim 9, wherein at least one said “k”-th silicon carbide layer further comprises:
an epitaxially grown by a Chemical Vapor Deposition (CVD) process silicon carbide layer, or an epitaxially grown by a molecular beam epitaxy (MBE) process silicon carbide layer.

11. The structure of claim 1; wherein said silicon semiconductor material further includes a plurality of M silicon semiconductor material layers; wherein said first silicon semiconductor material layer includes a bottom surface of said silicon semiconductor material; wherein said last M-th layer includes a top surface of said silicon semiconductor material; each said subsequent “i”-th layer overlying said preceding “i−1”-th layer; each said “i”-th silicon semiconductor material layer having an “i”-th conductivity type comprising said first conductivity type, or said second conductivity type; each said “i”-th silicon semiconductor material layer having an “i”-th dopant concentration; each said subsequent “i”-th silicon semiconductor material layer being grown on said preceding “i−1”-th silicon semiconductor material layer; “i” is an integer greater than 1, “i” is an integer less or equal to M, M is an integer.

12. The structure of claim 11, wherein at least one said “i”-th silicon semiconductor material layer further comprises:
an epitaxially grown by a Chemical Vapor Deposition (CVD) process silicon semiconductor material layer, or an epitaxially grown by a molecular beam epitaxy (MBE) process silicon semiconductor material layer.

13. The structure of claim 1, wherein said bonding layer further comprises:
a silicon dioxide layer.

14. The structure of claim 1, wherein said bonding layer further comprises: a silicon layer.

15. The structure of claim 1, wherein said bonding layer further comprises:
a carbon layer.

16. The structure of claim 1, wherein said bonding layer further comprises:
a metal silicided layer selected from the group consisting of:
a tungsten silicide layer; a titanium silicide layer; and a cobalt silicide layer.

17. The structure of claim 1 further including:
at least one separation plug formed in said silicon semiconductor material;
said separation plug extending from said top surface of said silicon semiconductor material into said silicon carbide substrate at a separation plug depth level, wherein said separation plug is configured to block the coupling between at least two adjacent active/passive structures, wherein each said active/passive structure is formed in said silicon semiconductor material, said first active/passive structure extending from said top surface of said silicon semiconductor material into said silicon semiconductor material at a first active/passive structure depth level, said second active/passive structure extending from said top surface of said silicon semiconductor material into said silicon semiconductor material at a second active/passive structure depth level.

18. The structure of claim 17, wherein said separation plug further includes:
a trench filled with a material selected from the group consisting of:
an oxide material, polysilicon material, a metal material, a silicided material, a tungsten silicide material, a titanium silicide material, a cobalt silicide material, and a platinum silicide material.

19. A silicon carbide based silicon structure comprising:
a silicon carbide substrate; and
a silicon semiconductor material having a top surface; said silicon semiconductor material being grown on said silicon carbide substrate.

20. The structure of claim 19, wherein said silicon carbide substrate is of a first conductivity type, said silicon carbide substrate having a first dopant concentration; said silicon semiconductor material being of a second conductivity type, said silicon semiconductor material having a second dopant concentration.

21. The structure of claim 20, wherein said first dopant concentration of said silicon carbide substrate is equal or greater than said second dopant concentration of said silicon semiconductor material.

22. The structure of claim 20, wherein said first dopant concentration of said silicon carbide substrate is lower than said second dopant concentration of said silicon semiconductor material.

23. The structure of claim 20, wherein said first conductivity of said silicon carbide is of P type.

24. The structure of claim 20, wherein said first conductivity of said silicon carbide is of N type.

25. The structure of claim 20, wherein said second conductivity type of said silicon semiconductor material is of P type.

26. The structure of claim 20, wherein said second conductivity type of said silicon semiconductor material is of N type.

27. The structure of claim 19; wherein said silicon carbide substrate further includes a plurality of N silicon carbide layers; wherein said first silicon carbide layer includes a bottom surface of said silicon carbide substrate; wherein said last N-th layer includes a top surface of said silicon carbide substrate; each said subsequent “k”-th layer overlying said preceding “k−1”-th layer; each said “k”-th silicon carbide layer having a “k”-th conductivity type comprising said first conductivity type, or said second conductivity type; each said “k”-th silicon carbide layer having a “k”-th dopant concentration; each said subsequent “k”-th silicon carbide layer being grown on said preceding “k−1”-th silicon carbide layer; “k” is an integer greater than 1, “k” is an integer less or equal to N, N is an integer.

28. The structure of claim 27, wherein at least one said “k”-th silicon carbide layer further comprises:
an epitaxially grown by a Chemical Vapor Deposition (CVD) process silicon carbide layer, or an epitaxially grown by a molecular beam epitaxy (MBE) process silicon carbide layer.

29. The structure of claim 19; wherein said silicon semiconductor material further includes a plurality of M silicon semiconductor material layers; wherein said first silicon semiconductor material layer includes a bottom surface of said silicon semiconductor material; wherein said last M-th layer includes a top surface of said silicon semiconductor material; each said subsequent “i”-th layer overlying said preceding “i−1”-th layer; each said “i”-th silicon semiconductor material layer having an “i”-th conductivity type comprising said first conductivity type, or said second conductivity type; each said “i”-th silicon semiconductor material layer having an “i”-th dopant concentration; each said subsequent “i”-th silicon semiconductor material layer being grown on said preceding “i−1”-th silicon semiconductor material layer; “i” is an integer greater than 1, “i” is an integer less or equal to M, M is an integer.

30. The structure of claim 29, wherein at least one said “i”-th silicon semiconductor material layer further comprises:
an epitaxially grown by a Chemical Vapor Deposition (CVD) process silicon semiconductor material layer, or an epitaxially grown by a molecular beam epitaxy (MBE) process silicon semiconductor material layer.

31. The structure of claim 19 further including:
at least one separation plug formed in said silicon semiconductor material;
said separation plug extending from said top surface of said silicon semiconductor material into said silicon carbide substrate at a separation plug depth level, wherein said separation plug is configured to block the coupling between at least two adjacent active/passive structures, wherein each said active/passive structure is formed in said silicon semiconductor material, said first active/passive structure extending from said top surface of said silicon semiconductor material into said silicon semiconductor material at a first active/passive structure depth level, said second active/passive structure extending from said top surface of said silicon semiconductor material into said silicon semiconductor material at a second active/passive structure depth level.

32. The structure of claim 31, wherein said separation plug further includes:
a trench filled with a material selected from the group consisting of:
an oxide material, a polysilicon material, a metal material, a silicided material, a tungsten silicide material, a titanium silicide material, a cobalt silicide material, and a platinum silicide material.
